(19) United States
(12) Patent Application Publication
(10) Pub. No.: US 2026/0222020 A1
(43) Pub. Date: Jul. 30, 2026

(54) MULTI-CHAIN RADIO CIRCUIT SYSTEM, QUADRATURE DIVIDER CIRCUIT, AND SYNCHRONIZATION METHOD

(71) Applicant: Chongqing WUQI Microelectronics Co., Ltd., Chongqing (CN)

(72) Inventor: Michael P. MACK, Kula, HI (US)

(73) Assignee: Chongqing WUQI Microelectronics Co., Ltd., Chongqing (CN)

(21) Appl. No.: 19/148,324

(22) PCT Filed: Feb. 16, 2023
(86) PCT No.: PCT/CN2023/076478

§ 371 Date: Jul. 16, 2025

(30) Foreign Application Priority Data
Jan. 17, 2023 (CN) 2023100752905

(51) Int. Cl. H04B 7/0413; H04B 7/06

(52) U.S. Cl. CPC H04B 7/0413; H04B 7/06952

(57) ABSTRACT

Provided are a multi-chain radio circuit system, a quadrature divider circuit and a synchronization method. The quadrature divider circuit comprises: a logic unit and k self-resetting quadrature dividers, k is a natural number greater than 1. When a clock enable signal is valid, a clock signal is enabled as a gated clock, and when the clock enable signal is invalid, the clock signal is disabled. The frequency of the clock signal is twice that of a local oscillator signal. Each self-resetting quadrature divider is connected to an output terminal of the logic unit. When the clock signal is disabled, self-resetting is performed, and when the clock signal is enabled, an in-phase local oscillator signal and a quadrature local oscillator signal required for transmission and reception of a corresponding radio circuit are generated. During radio wake-up in the present disclosure, beam steering is always employed without sacrificing link throughput. Each radio circuit uses its own local oscillator signal, simplifying the routing and reducing the generation of radiated spurious tones. Furthermore, there is no need to use an explicit reset signal or to ensure that the reset signal satisfies potentially stringent timing constraints.

### TECHNICAL FIELD

The present disclosure relates to the field of integrated circuit design, and in particular to a multi-chain radio circuit system, a quadrature divider circuit and a synchronization method.

### BACKGROUND

In radio communications, throughput and range can be increased by employing radio devices with more than one antenna on one or both ends of the link. Each antenna is typically connected to a separate radio circuit, and each radio can be independently modulated. This allows for increased throughput and range through MIMO and beam-steering techniques.

Beam steering is a method of altering the radiation pattern of an array of antennas by changing the relative position or the relative RF carrier phase of each antenna. In most implementations, antenna positions are fixed, and beam steering is performed by altering the carrier phases. This is done in such a way that the signal strength at a remote target is higher than it would be without beam steering, which in turn leads to better throughput and range. However, to achieve this, each radio must first determine the correct antenna phases needed to steer the radiation pattern towards the other participant in the link. This process is known as sounding, and it consumes time and system resources. Therefore, it is desirable to minimize its occurrence.

Therefore, how to avoid issues such as reduced link throughput and consumption of time and system resources caused by frequent sounding has become one of the urgent issues for those skilled in the art to solve.

It should be noted that the foregoing description of the Background is provided solely to facilitate a clear and complete description of the technical solutions in this application and to facilitate the understanding of those skilled in the art. It should not be assumed that the aforementioned technical solutions are known to those skilled in the art solely because they are described in the Background section of this application.

### SUMMARY

In view of the foregoing drawbacks in the prior art, an objective of the present disclosure is to provide a multi-chain radio circuit system, a quadrature divider circuit and a synchronization method, to solve the issues such as reduced link throughput and consumption of time and system resources caused by re-sounding during radio wake-up in the prior art.

To achieve the foregoing objective and other related objectives, the present disclosure provides a quadrature divider circuit. The quadrature divider circuit includes at least:

A logic unit and k self-resetting quadrature dividers, where k is a natural number greater than 1.

A first input terminal of the logic unit is connected to a clock enable signal, a second input terminal of the logic unit is connected to a clock signal, and a gated clock is output; and when the clock enable signal is valid, the clock signal is enabled as the gated clock, and when the clock enable signal is invalid, the clock signal is disabled, where a frequency of the clock signal is twice that of a local oscillator signal.

Each self-resetting quadrature divider is connected to an output terminal of the logic unit. When the clock signal is disabled, self-resetting is performed, and when the clock signal is enabled, an in-phase local oscillator signal and a quadrature local oscillator signal required for transmission and reception of a corresponding radio circuit are generated.

Optionally, each self-resetting quadrature divider includes a reset unit and a quadrature divider.

The reset unit is connected to an output terminal of the logic unit. When the gated clock is active, an invalid reset signal is generated, and when the gated clock is stopped for a preset time, a valid reset signal is generated.

An input terminal of the quadrature divider is connected to the output terminal of the logic unit, a reset terminal of the quadrature divider is connected to an output terminal of the reset unit, when the reset signal is valid, the quadrature divider is reset, and when the reset signal is invalid, the quadrature divider generates the in-phase local oscillator signal and the quadrature local oscillator signal based on the gated clock.

Optionally, the reset unit includes a timer and a logic NOT gate; the timer is connected to the output terminal of the logic unit, and measures duration for which the gated clock is stopped and generates a corresponding timing voltage; and the logic NOT gate is connected to an output terminal of the timer, and generates the valid reset signal when the timing voltage reaches a preset value.

Optionally, the timer includes a current source, a pull-down transistor, and a capacitor, one terminal of the current source is connected to a supply voltage, and the other terminal of the current source is grounded through the pull-down transistor; a control terminal of the pull-down transistor is connected to the output terminal of the logic unit; and the capacitor is connected in parallel across two terminals of the pull-down transistor.

Further optionally, the quadrature divider circuit further includes an enable synchronization unit, and the enable synchronization unit includes n-stage D flip-flops, where n is a natural number greater than or equal to 1.

When n is equal to 1, a data input of the D flip-flop is connected to the clock enable signal, a clock input of the D flip-flop is connected to the clock signal, and an output of the D flip-flop is connected to the first input terminal of the logic unit.

When n is greater than or equal to 2, the D flip-flops are cascaded sequentially, a data input of the first-stage D flip-flop is connected to the clock enable signal, a data input of each subsequent-stage D flip-flop is connected to an output of the previous-stage D flip-flop in sequence, clock inputs of all D flip-flops are connected to the clock signal, and an output of the last-stage D flip-flop is connected to the first input terminal of the logic unit.

To achieve the foregoing objective and other related objectives, the present disclosure provides a quadrature divider circuit. The quadrature divider circuit includes at least:

A logic unit and k self-resetting quadrature dividers, where k is a natural number greater than 1;

A first input terminal of the logic unit is connected to a clock enable signal, and a second input terminal of the logic unit is connected to a first clock signal; when the clock enable signal is valid, the first clock signal is enabled, and when the clock enable signal is invalid, the first clock signal is disabled; a differential gated clock is generated based on an output signal of the logic unit and a second clock signal, where the first clock signal and the second clock signal are differential signals, and frequencies of the first clock signal and the second clock signal are twice that of a local oscillator signal.

Each self-resetting quadrature divider receives the gated clock. when the first clock signal is disabled, self-resetting is performed, and when the first clock signal is enabled, an in-phase local oscillator signal and a quadrature local oscillator signal required for transmission and reception of a corresponding radio circuit are generated.

Optionally, each self-resetting quadrature divider includes a reset unit and a quadrature divider.

The reset unit is connected to an output terminal of the logic unit. When the output signal of the logic unit is running, an invalid reset signal is generated, and when the output signal of the logic unit is stopped, a valid reset signal is generated.

An input terminal of the quadrature divider is connected to the gated clock, a reset terminal of the quadrature divider is connected to an output terminal of the reset unit, when the reset signal is valid, the quadrature divider is reset, and when the reset signal is invalid, the quadrature divider generates the in-phase local oscillator signal and the quadrature local oscillator signal based on the gated clock.

Optionally, the reset unit includes an XOR gate. The input terminals of the XOR gate are respectively connected to the output terminal of the logic unit and the second clock signal, and an output terminal of the XOR gate is connected to the reset terminal of the quadrature divider.

Further optionally, the quadrature divider circuit further includes an enable synchronization unit, and the enable synchronization unit includes n-stage D flip-flops, where n is a natural number greater than or equal to 1.

When n is equal to 1, a data input of the D flip-flop is connected to the clock enable signal, a clock input of the D flip-flop is connected to the first clock signal, and an output of the D flip-flop is connected to the first input terminal of the logic unit.

When n is greater than or equal to 2, the D flip-flops are cascaded sequentially, a data input of the first-stage D flip-flop is connected to the clock enable signal, a data input of each subsequent-stage D flip-flop is connected to an output of the previous-stage D flip-flop in sequence, clock inputs of all D flip-flops are connected to the first clock signal, and an output of the last-stage D flip-flop is connected to the first input terminal of the logic unit.

Further optionally, the gated clock is routed to each self-resetting quadrature divider through an on-chip routing path.

To achieve the foregoing objective and other related objectives, the present disclosure provides a multi-chain radio circuit system. The multi-chain radio circuit system includes at least:

A local oscillator signal generation module, k radio circuits, and the foregoing quadrature divider circuit.

The local oscillator signal generation module is configured to generate a clock signal.

The quadrature divider circuit is connected to an output terminal of the local oscillator signal generation module, and generates an in-phase local oscillator signal and a quadrature local oscillator signal required for transmission and reception for each of the k radio circuits based on the clock signal.

Each radio circuit receives the corresponding in-phase local oscillator signal and quadrature local oscillator signal, and is configured to implement transmission and reception of a radio signal.

Optionally, each radio circuit includes a transmit path, a receive path, a switching circuit, and an antenna.

The transmit path receives a first group of mutually quadrature local oscillator signals, and performs up-conversion based on the first group of mutually quadrature local oscillator signals to obtain a to-be-transmitted radio frequency signal.

The receive path receives a second group of mutually quadrature local oscillator signals, and performs down-conversion on the received radio frequency signal based on the second group of mutually quadrature local oscillator signals.

A first terminal of the switching circuit is connected to the antenna, and a second terminal of the switching circuit switches between the transmit path and the receive path.

To achieve the foregoing objective and other related objectives, the present disclosure further provides a synchronization method for a quadrature divider circuit. The synchronization method for the quadrature divider circuit includes at least:

When a clock enable signal is valid, enabling a clock signal as a gated clock, providing the gated clock to each of k radio circuits, and generating, by a quadrature divider in each radio circuit, an in-phase local oscillator signal and a quadrature local oscillator signal required for transmission and reception of the current radio circuit based on the gated clock, where a frequency of the clock signal is twice that of a local oscillator signal, and k is a natural number greater than 1.

When the clock enable signal is invalid, disabling the clock signal, wherein the quadrature divider in each of the radio circuits performs a self-reset and resumes operation from a preset reset state after the clock signal is re-enabled.

To achieve the foregoing objective and other related objectives, the present disclosure further provides a synchronization method for a quadrature divider circuit, the synchronization method for the quadrature divider circuit includes at least:

When a clock enable signal is valid, enabling a first clock signal, generating a differential gated clock based on the first clock signal and a second clock signal, providing the gated clock to each of k radio circuits, and generating, by a quadrature divider in each radio circuit, an in-phase local oscillator signal and a quadrature local oscillator signal required for transmission and reception of the current radio circuit based on the gated clock, where the first clock signal and the second clock signal are differential signals, frequencies of the first clock signal and the second clock signal are twice that of a local oscillator signal, and k is a natural number greater than 1.

When the clock enable signal is invalid, disabling the first clock signal, wherein the quadrature divider in each of the radio circuits performs a self-reset and resumes operation from a preset reset state after the clock signal is re-enabled.

Optionally, the synchronization method for the quadrature divider circuit further includes a step of synchronizing the clock enable signal and a clock signal before the gated clock is generated.

As described above, the multi-chain radio circuit system, the quadrature divider circuit, and the synchronization method of the present disclosure have the following beneficial effects:

The multi-chain radio circuit system, the quadrature divider circuit, and the synchronization method of the present disclosure can synchronously modulate the clock enable signal and the clock signal, and detect the modulated signals. When it is detected that the clock signal is disabled, a self-reset signal of the frequency divider is generated. During radio wake-up, beam steering is always employed without sacrificing link throughput. Each radio circuit uses its own local oscillator signal, simplifying the wiring and reducing the generation of radiated spurious tones. Additionally, there is no need to use an explicit reset signal or to ensure that the reset signal satisfies potentially stringent timing constraints.

### BRIEF DESCRIPTION OF DRAWINGS

FIG. 1 is a schematic diagram showing the structure of a radio circuit.

FIG. 2 is a schematic diagram showing the relationship between an in-phase local oscillator signal and a quadrature local oscillator signal.

FIG. 3 is a schematic diagram showing the structure of a quadrature divider.

FIG. 4 is a schematic diagram showing the principle of generating an in-phase local oscillator signal and a quadrature local oscillator signal.

FIG. 5 is a schematic diagram showing the structure of a latch.

FIG. 6 is a schematic diagram showing a multi-chain radio circuit with a local quadrature divider.

FIG. 7 is a schematic diagram showing the phase mismatch between in-phase local oscillator signal waveforms caused by an initial random state.

FIG. 8 is a schematic diagram showing the principle of a beam steering failure caused by an unknown local oscillator phase during power up.

FIG. 9 is a schematic diagram showing a multi-chain radio circuit including a shared quadrature divider.

FIG. 10 is a schematic diagram showing a multi-chain radio circuit including a synchronous reset signal for a local oscillator frequency divider.

FIG. 11 is a schematic structural diagram of a quadrature divider circuit according to the present disclosure.

FIG. 12 is a schematic structural diagram of a self-resetting frequency divider according to the present disclosure.

FIG. 13 is a schematic diagram showing a synchronization method for a quadrature divider circuit according to the present disclosure.

FIG. 14 is another schematic structural diagram of a quadrature divider circuit according to the present disclosure.

FIG. 15 is another schematic structural diagram of a self-resetting frequency divider according to the present disclosure.

FIG. 16 is another schematic diagram of the principle of a synchronization method for a quadrature divider circuit according to the present disclosure.

FIG. 17 is a schematic structural diagram of a multi-chain radio circuit system according to the present disclosure.

FIG. 18 is a schematic structural diagram of a radio circuit according to the present disclosure.

FIG. 19 is a schematic diagram of simulation waveforms of a gated clock and an output signal of a self-resetting frequency divider according to the present disclosure.

### REFERENCE NUMERALS

11 Transmit path
12 Receive path
13 Quadrature divider
131 Tristate buffer
132 Memory cell
14 Switch
15 Local oscillator signal generation circuit
16 Shared quadrature divider
2 Quadrature divider circuit
21 Logic unit
22a, 22b First and second self-resetting quadrature dividers
221 Reset unit
221a Timer
221b Logic NOT gate
222 Quadrature divider
23a, 23b First and second on-chip routing paths
24 Enable synchronization unit
3 Local oscillator signal generation module
4a, 4b First and second radio circuits
41 Digital-to-analog converter
42 First analog baseband
43 Upconverter
44 Power amplifier
45 Switching circuit
46 Low noise amplifier
47 Downconverter
48 Second analog baseband
49 Analog-to-digital converter

### DETAILED DESCRIPTION

The embodiments of the present disclosure are described below through particular specific examples, and those skilled in the art can easily understand other advantages and efficacy of the present disclosure through the content disclosed in this specification. The present disclosure may alternatively be implemented or applied through other different specific embodiments, and various modifications or changes may be made to various details in this specification based on different views and applications without departing from the spirit of the present disclosure.

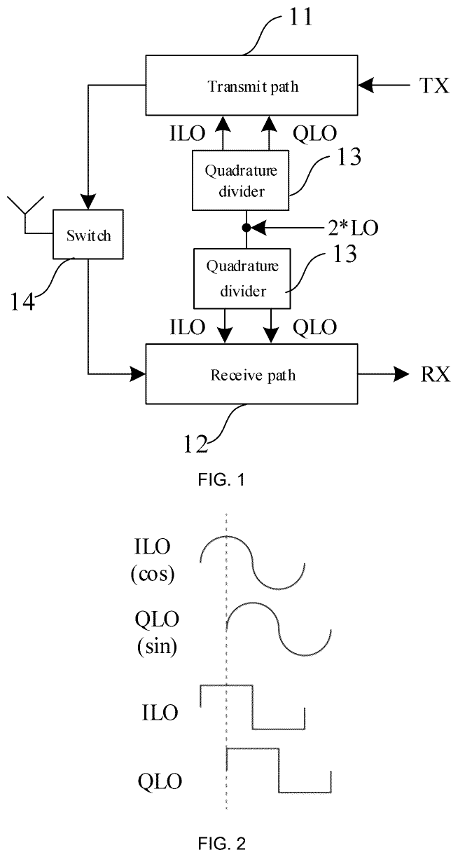

Refer to FIG. 1 to FIG. 19. It should be noted that the drawings provided in this embodiment schematically describe the basic concept of the present disclosure, and only the components related to the present disclosure are shown in the accompanying drawings, which are not drawn in accordance with the number, shape, and size of the components in actual embodiments, and the actual implementation of the components, the number, and the proportion of the components may be changed in any manner, and the layout of the components may be more complex.

To enhance the effectiveness of the sounding process, it is essential to precisely control the carrier phase of each radio circuit signal. However, it is difficult to achieve precise control with conventional radio circuit architectures. FIG. 1 is a diagram of a radio circuit architecture that can implement such control. As shown in FIG. 1, a transmit signal TX (baseband) is converted into a radio frequency signal through a transmit path 11, and an antenna is connected through a switch 14 to transmit the radio frequency signal. The radio frequency signal is received through the antenna, and is transmitted to a receive path 12 through the switch 14, and is converted into a receive signal RX (baseband). The receive signal RX and the transmit signal TX are split into signals on two quadrature paths, which are respectively referred to as an in-phase path (or an I path) and a quadrature path (or a Q path). The amplitude and phase of an RF carrier can be modulated independently by processing a signal in this manner, thereby increasing the data rate at a given bandwidth. One key requirement is to provide local oscillator (LO) signals with a 90-degree phase difference. In the transmit path 11 and the receive path 12, an input signal is multiplied by two local oscillator signals with a 90-degree phase difference. The two local oscillator signals with a 90-degree phase difference are respectively referred to as an in-phase local oscillator (ILO) signal and a quadrature local oscillator (QLO) signal. As shown in FIG. 2, the in-phase local oscillator signal ILO may be considered as a cosine wave (cos), and the quadrature local oscillator signal QLO may be considered as a sine wave (sin). However, it is very difficult to design a sine wave and a linear mixer in practice, and therefore a square wave and a switch mixer are used instead. It can be seen from FIG. 2 that an in-phase local oscillator signal ILO in a square wave form and an in-phase local oscillator signal ILO in a cosine wave form have consistent phases, a quadrature local oscillator signal QLO in a square wave form and a quadrature local oscillator signal QLO in a sine wave form have consistent phases, and the in-phase local oscillator signal ILO leads the quadrature local oscillator signal QLO by 90 degrees.

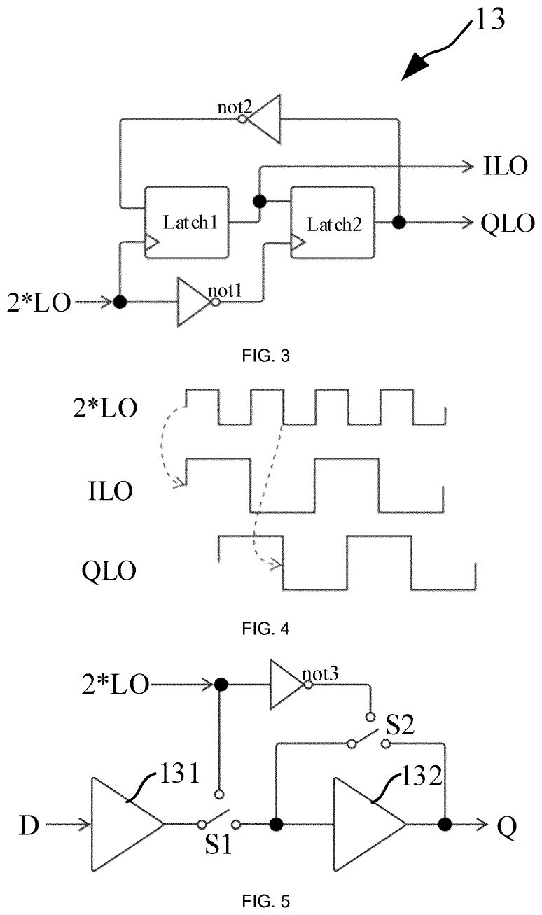

As shown in FIG. 1, the in-phase local oscillator signal ILO and the quadrature local oscillator signal QLO are typically generated by using a quadrature divider 13. As shown in FIG. 3, the quadrature divider 13 is consists of a cascaded pair of latches Latch1 and Latch2, which are respectively driven by an input clock and its inverted clock (the inverted clock is obtained through a logic NOT gate not1), and the frequency of the input clock is twice (denoted as 2*LO) that of the required local oscillator signal LO. The latch Latch1 outputs the in-phase local oscillator signal ILO, the latch Latch2 outputs the quadrature local oscillator signal QLO, and an output signal of the latch Latch2 is connected to an input terminal of the latch Latch1 via a logic NOT gate not2. As shown in FIG. 4, the waveform of the in-phase local oscillator signal ILO is asserted on the rising edge of the input clock, and the waveform of the quadrature local oscillator signal QLO is asserted on the falling edge of the input clock, the frequency of the signals is half of that of the input clock 2*LO. It should be noted that the circuit can be implemented in any digital logic system. However, in CMOS technology, it is typically implemented using CMOS logic circuits. It should also be noted that the diagrams shown in this application are drawn with single-ended signals for simplicity. Differential implementations are frequently used as well.

Although the cascaded latch circuit in FIG. 3 can generate quadrature waveforms, it has a significant drawback when applied to beam steering, that is, the output of the latch may exhibit indeterminate and undefined states. As shown in FIG. 5, a typical latch consists of a tristate buffer 131 and a memory cell 132. An input terminal of the tristate buffer 131 is connected to an input signal D, and an output terminal of the tristate buffer 131 is connected to an input terminal of the memory cell 132 through a first switch S1. The memory cell 132 generates an output signal Q of the latch. A second switch S2 is connected across two terminals of the memory cell 132. A control terminal of the first switch S1 is connected to the input clock 2*LO, and a control terminal of the second switch S2 is connected to the inverted clock (the inverted clock is obtained through a logic NOT gate not3) of the input clock 2*LO. When the input clock 2*LO is at a high level, the first switch S1 is open, and the second switch S2 is closed. In this state, the tristate buffer 131 passes the input signal D to the input terminal of the memory cell 132. When the input clock 2*LO goes low, the first switch S1 is closed, the second switch S2 is open, and the output signal of the tristate buffer 131 is transmitted to the memory cell 132. The problem occurs when the latch is powered on for the first time. If the first switch S1 is open and the second switch S2 is closed, the memory cell 132 will have no input drive, and its output will settle to a random state and become indeterminate. In the quadrature divider circuit, this random initial state causes uncertainty in the output phase. What complicates this issue further is that the input clock 2*LO typically has runt and glitch pulses during startup, which destabilize the initial clock. Before the clock stabilizes, such waveforms may cause unpredictable transitions in the frequency divider output waveform.

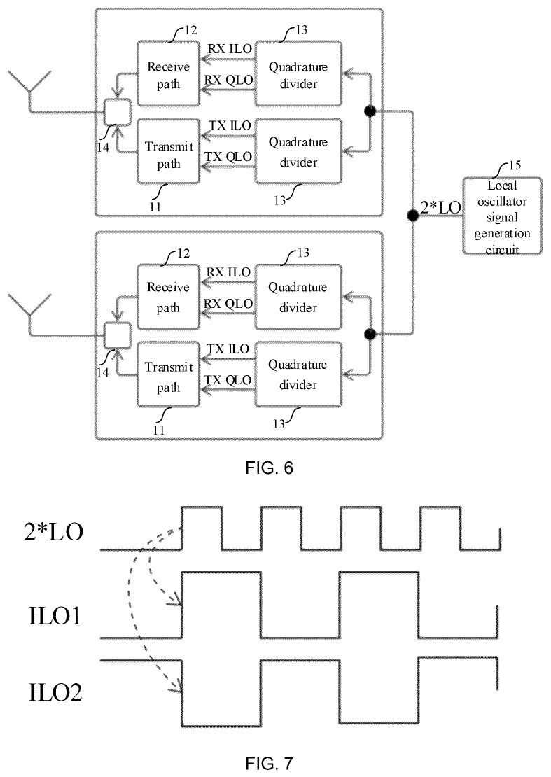

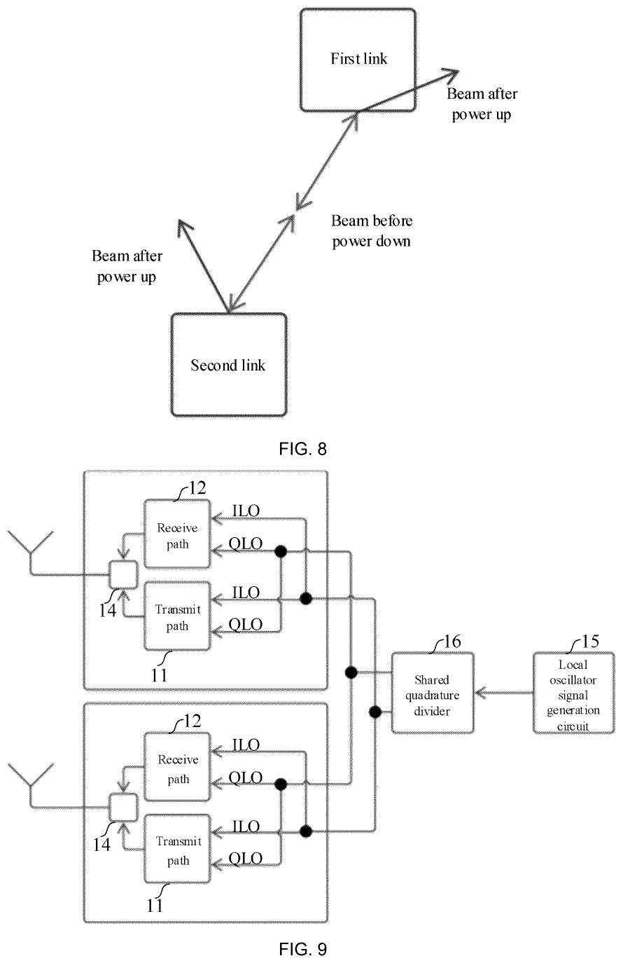

FIG. 6 shows a multi-chain radio circuit with local quadrature dividers. A local oscillator signal generation circuit 15 generates the input clock 2*LO and provides the input clock 2*LO to two links. Each link has two quadrature dividers 13 (i.e., there are four quadrature dividers 13 in total). When the radio wakes up from a power-off state, each of the four quadrature dividers 13 will have a random output phase difference. As shown in FIG. 7, as an example, an in-phase local oscillator signal transitions on the leading edge of the waveform of the input clock 2*LO. However, due to the different initial states of each quadrature divider 13, in the two links, the leading edges of the in-phase local oscillator signals ILO1 and ILO2 waveforms exhibit a 180-degree phase difference, leading to phase mismatch. As shown in FIG. 8, sounding is completed on the first link and the second link before powering down, and communication is performed normally. After repowering, the previous sounding is disrupted by adding a random beam steering angle relative to the previous sounding result, necessitating re-sounding. This incorrect beam steering angle can seriously degrade the link throughput until a new sounding is completed.

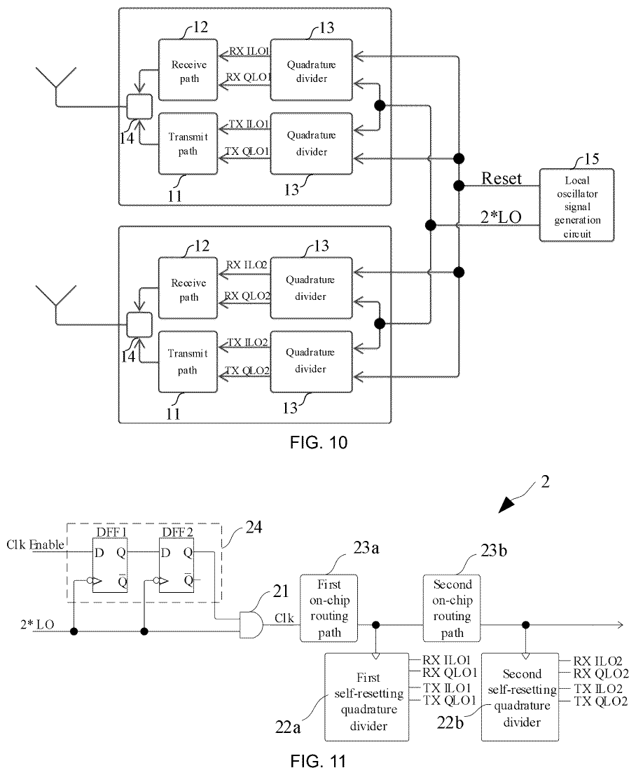

To solve the above issues, one solution is to avoid using beam steering when the radio wakes up from any power-off state. This will result in a decrease in throughput each time the radio wakes up, and this will persist until new sounding is completed. Moreover, in low-power applications, performing new sounding each time the radio circuit wakes up may become impractical, potentially resulting in the circuit maintaining a lower throughput state for an extended period. In addition, the use of this solution may further require enabling all quadrature dividers when the radio circuit is in a wake-up state and the sounding is completed. This may result in higher power consumption in receive, transmit, and idle modes, as the entire local oscillator signal path must remain enabled to maintain effective sounding. Another solution is to use a shared quadrature divider 16 to generate the in-phase local oscillator signal ILO and the quadrature local oscillator signal QLO, which are then sent to each link, as shown in FIG. 9. However, this architecture also has several drawbacks. First, the requirements of the shared in-phase and quadrature wiring are much more stringent than those of the local wiring in FIG. 6. The additional parasitic capacitance and resistance introduced will cause the I-Q phase relationship to deviate significantly from the ideal 90 degrees. Secondly, the extensive wiring of local oscillator signals increases the likelihood of spurious radiated or conducted leakage tones. If these spurious tones leak to the radio frequency (RF) receiver circuit, they will downconvert to baseband and manifest as direct current (DC) offsets. If these spurious leakage tones reach the antenna, their magnitude and phase will vary with the surrounding environment of the antenna, making this dynamic offset difficult to calibrate. Another solution is to use a synchronous reset to force all quadrature dividers to start at the same phase, as shown in FIG. 10. The local oscillator signal generation circuit 15 generates the input clock 2*LO and a reset signal Reset, which are simultaneously routed to each quadrature divider 13. Since each quadrature divider 13 must be reset on the same edge of the input clock 2*LO, the routing delays of the input clock 2*LO and the reset signal Reset to the quadrature divider 13 should be much shorter than the clock period of 2*LO. However, it can be difficult to meet this requirement, especially for long routes at high frequencies.

Based on the foregoing reasons, the present disclosure provides a quadrature divider circuit which modulates the waveform of the clock signal 2*LO, detects the modulation in the frequency divider, and uses the detected output to reset the quadrature divider, thereby avoiding the uncertainty in the output phase of each quadrature divider during power up and wake-up.

### Embodiment 1

As shown in FIG. 11, this embodiment provides a quadrature divider circuit 2. The quadrature divider circuit 2 includes:

a logic unit 21 and k self-resetting quadrature dividers, where k is a natural number greater than 1.

As shown in FIG. 11, a first input terminal of the logic unit 21 is connected to a clock enable signal Clk Enable, a second input terminal of the logic unit 21 is connected to a clock signal 2*LO, and a gated clock Clk is output. When the clock enable signal Clk Enable is valid, the clock signal 2*LO is enabled as the gated clock Clk, and when the clock enable signal Clk Enable is invalid, the clock signal 2*LO is disabled. The frequency of the clock signal 2*LO is twice that of a local oscillator signal.

Specifically, in this embodiment, the logic unit 21 is a logic AND gate. A first input terminal of the logic AND gate is connected to the clock enable signal Clk Enable, and a second input terminal of the logic AND gate is connected to the clock signal 2*LO. When the clock enable signal Clk Enable is at a high level (valid), the gated clock Clk is the clock signal 2*LO. When the clock enable signal Clk Enable is at a low level (invalid), the gated clock Clk has no output (low level). In practical use, any logic unit that can implement the foregoing logic is applicable to the present disclosure, and is not limited to this embodiment described herein.

It should be noted that if the clock enable signal Clk Enable and the clock signal 2*LO are synchronous, the gated clock Clk may be directly obtained based on the logic unit 21. However, in practical use, because the clock enable signal Clk Enable and the clock signal 2*LO may come from different clock domains and may not meet timing requirements, the clock enable signal Clk Enable and the clock signal 2*LO are usually not treated as synchronous. Therefore, it is necessary to synchronize the clock enable signal Clk Enable with the clock signal 2*LO to ensure that a clock gate in the logic unit 21 does not malfunction. As shown in FIG. 11, as another implementation of the present disclosure, the quadrature divider circuit 2 further includes an enable synchronization unit 24, an input terminal of the enable synchronization unit 24 is connected to the clock enable signal Clk Enable and the clock signal 2*LO, and an output terminal of the enable synchronization unit 24 is connected to the first input terminal of the logic unit 21. In this embodiment, the enable synchronization unit 24 includes n-stage D flip-flops, n is a natural number greater than or equal to 1. When n is equal to 1, a data input of the D flip-flop is connected to the clock enable signal Clk Enable, a clock input of the D flip-flop is connected to the clock signal 2*LO, and an output of the D flip-flop is connected to the first input terminal of the logic unit 21. When n is greater than or equal to 2, the D flip-flops are cascaded sequentially, a data input of the first-stage D flip-flop is connected to the clock enable signal Clk Enable, a data input of each subsequent-stage D flip-flop is connected to an output of the previous-stage D flip-flop in sequence, clock inputs of all D flip-flops are connected to the clock signal 2*LO, and an output of the last-stage D flip-flop is connected to the first input terminal of the logic unit 21. As an example, n is 2, and the enable synchronization unit 24 includes a first D flip-flop DFF1 and a second D flip-flop DFF2. A data input of the first D flip-flop DFF1 receives Clk Enable, and a clock input of the first D flip-flop DFF1 receives the clock signal 2*LO. A data input of the second D flip-flop DFF2 is connected to an output terminal of the first D flip-flop DFF1, a clock input of the second D flip-flop DFF2 receives the clock signal 2*LO, and an output terminal of the second D flip-flop DFF2 is connected to the first input terminal of the logic unit 21. The quantity of D flip-flops in the enable synchronization unit 24 may be set as required, and two D flip-flops are typically used to reduce the probability of metastability to nearly zero, or a single flip-flop may be used. In this case, the probability of metastability is still very low, but is higher than the possibility of metastability in the case of two flip-flops. Because the costs are low, using two D flip-flops is considered a good engineering practice. Certainly, more than two D flip-flops may be disposed of without considering costs. However, the quantity is not limited to this embodiment.

As shown in FIG. 11, each self-resetting quadrature divider is connected to an output terminal of the logic unit 21, when the clock signal 2*LO is disabled, self-resetting is performed, and when the clock signal 2*LO is enabled, an in-phase local oscillator signal and a quadrature local oscillator signal required for transmission and reception of a corresponding radio circuit are generated.

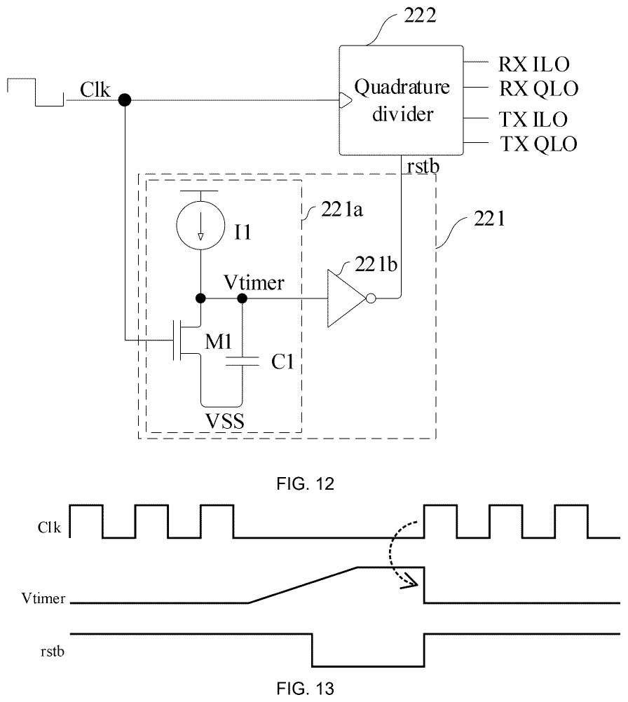

Specifically, in this embodiment, k is set to 2, and the self-resetting quadrature dividers are respectively denoted as a first self-resetting quadrature divider 22a and a second self-resetting quadrature divider 22b. The first self-resetting quadrature divider 22a and the second self-resetting quadrature divider 22b, respectively, provide their corresponding radio circuits with an in-phase local oscillator signal and a quadrature local oscillator signal required for transmission and reception. In practical use, the value of k may be set as required, and is not limited to this embodiment. As shown in FIG. 12, each self-resetting quadrature divider includes a reset unit 221 and a quadrature divider 222. The reset unit 221 is connected to the output terminal of the logic unit 21. When the gated clock Clk is active, an invalid reset signal rstb is generated, and after the gated clock Clk is stopped for a preset time, a valid reset signal rstb is generated. An input terminal of the quadrature divider 222 is connected to the output terminal of the logic unit 21, and a reset terminal of the quadrature divider 222 is connected to an output terminal of the reset unit 221. When the reset signal rstb is valid, the quadrature divider 222 is reset, and when the reset signal rstb is invalid, the quadrature divider 222 generates the in-phase local oscillator signal and the quadrature local oscillator signal based on the gated clock Clk.

More specifically, as shown in FIG. 12, as an example, the reset unit 221 includes a timer 221a and a logic NOT gate 221b. The timer 221a is connected to the output terminal of the logic unit 21, and measures the duration for which the gated clock Clk is stopped and generates a corresponding timing voltage Vtimer. The logic NOT gate 221b is connected to an output terminal of the timer 221a, and generates a valid reset signal when the timing voltage Vtimer reaches a preset value. In this example, the timer 221a includes a current source 11, a pull-down transistor M1, and a capacitor C1. One terminal of the current source 11 is connected to a supply voltage, and the other terminal of the current source 11 is grounded to VSS via the pull-down transistor M1. A control terminal of the pull-down transistor M1 is connected to the output terminal of the logic unit 21. The capacitor C1 is connected in parallel across two terminals of the pull-down transistor M1. As shown in FIG. 13, when the gated clock Clk is active, the pull-down transistor M1 pulls the timing voltage Vtimer to the ground VSS at every positive clock pulse, and the reset signal rstb remains high (invalid). When the gated clock Clk is stopped, the current source 11 gradually pulls the timing voltage Vtimer to the supply voltage, the reset signal rstb transitions low (valid), and all the quadrature dividers 222 are eventually reset. After a stop period of the gated clock Clk ends, the pull-down transistor M1 immediately pulls Vtimer low on the first clock leading edge, the reset signal rstb transitions high, and the quadrature dividers 222 all start from the known reset state. FIG. 13 only shows that the gated clock Clk is stopped for several periods. However, in practice, a period for which the clock is stopped may be much longer. Duration for which the clock signal 2*LO is disabled should be much longer than the time (that is, the time for which the reset signal is valid) required to reset the quadrature divider 222. The time for which the reset signal is valid depends on the values of the current source 11 and the capacitor C1 in the timer 221a, and may be configured as required.

More specifically, the quadrature divider 222 is configured to generate mutually quadrature signals. In this embodiment, the quadrature divider 222 provides four local oscillator signals, RX ILO, RX QLO, TX ILO, and TX QLO, to their corresponding radio circuits, and the phases of the local oscillator signals are sequentially spaced by 90 degrees. in practical use, one radio circuit may require local oscillator signals with more than four clock phases to achieve image rejection. For example, an architecture with eight phases spaced by 45 degrees allows a receiver to reject the third harmonic signal of an LO. Details are not described one by one herein. Any multi-phase LO divider structure having an indeterminate initial state is applicable to the present disclosure. As an example, the quadrature divider 222 uses the structure shown in FIG. 3. A reset transistor (not shown in the figure) is disposed at an output terminal of the latch Latch2. A control terminal of the reset transistor receives the reset signal rstb. When the reset signal rstb is valid, an output signal of the quadrature divider 222 is reset to a preset level (a high level or a low level). Output signals may be reset to corresponding levels or may be reset to the same level. The reset transistor may be disposed at any position of the quadrature divider 222 as required, but is not limited to this embodiment.

As shown in FIG. 11, the quadrature divider circuit 2 further includes k on-chip routing paths, configured to route the gated clock Clk to each self-resetting quadrature divider. In this embodiment, two on-chip routing paths are included, and are respectively denoted as a first on-chip routing path 23a and a second on-chip routing path 23b. The first on-chip routing path 23a receives the gated clock Clk, and routes the gated clock Clk to the first self-resetting quadrature divider 22a. The second on-chip routing path 23b is connected to an output terminal of the first on-chip routing path 23a, and routes the gated clock Clk to the second self-resetting quadrature divider 22b. The on-chip routing paths have delays, and these delays cause the self-resetting quadrature dividers to exit reset at slightly different time points. However, routing delays are fixed, and the fixed delays do not cause variations in sounding results (for example, these fixed delays are already included in the first time of sounding, and the subsequent sounding also includes these fixed delays.

### Embodiment 2

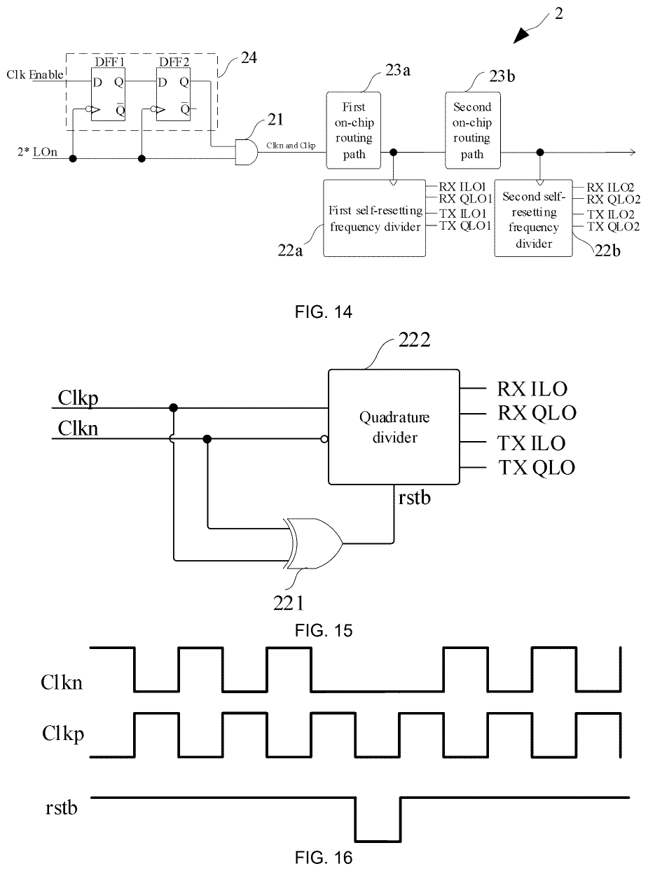

As shown in FIG. 14 and FIG. 15, this embodiment provides a quadrature divider circuit 2, and differences from Embodiment 1 lie in that the clock signal is a differential signal, and the modulation of the clock signal is implemented through two complementary signals of the differential signal pair.

Specifically, the first input terminal of the logic unit 21 is connected to the clock enable signal Clk Enable, and the second input terminal of the logic unit 21 is connected to a first clock signal 2*LOn (or 2*LOp). When the clock enable signal Clk Enable is valid, the first clock signal 2*LOn (or 2*LOp) is enabled, and when the clock enable signal Clk Enable is invalid, the first clock signal 2*LOn (or 2*LOp) is disabled. A differential gated clock pair, Clkn and Clkp, is generated based on an output signal of the logic unit 21 and a second clock signal 2*LOp (or 2*LOn). The first clock signal 2*LOn (or 2*LOp) and the second clock signal 2*LOp (or 2*LOn) are differential signals, and the frequencies of the first clock signal and the second clock signal are twice that of a local oscillator signal.

Specifically, each self-resetting quadrature divider receives the gated clock Clkn and Clkp when the first clock signal 2*LOn (or 2*LOp) is disabled, self-resetting is performed, and when the first clock signal 2*LOn (or 2*LOp) is enabled, an in-phase local oscillator signal and a quadrature local oscillator signal required for transmission and reception of a corresponding radio circuit are generated. More specifically, each self-resetting quadrature divider includes a reset unit 221 and a quadrature divider 222. As an example, as shown in FIG. 15, the reset unit 221 includes an XOR gate. Input terminals of the XOR gate are respectively connected to the differential gated clock pair Clkn and Clkp, and an output terminal of the XOR gate is connected to the reset terminal of the quadrature divider 222. As shown in FIG. 16, the clock enable signal Clk Enable disables the first clock signal 2*LOn (or 2*LOp) based on the logic unit 21. During the disabled period, the gated clock Clk remains single-ended. In this example, the gated clock Clkn is disabled. A time period of disabling is detected through the XOR gate in each self-resetting quadrature divider. That is, after the gated clock Clkn remains disabled for half a clock period, the reset signal rstb is valid, and becomes invalid after a half clock period. When the gated clock Clkn has been disabled long enough, the reset signal rstb exhibits multiple low pulse signals during the disabled period. The reset signal rstb is used for resetting the quadrature divider 222.

Specifically, the structure of the enable synchronization unit 24 is the same as that in Embodiment 1, and the received clock signals are different. In this embodiment, the clock signal received by the D flip-flop in the enable synchronization unit 24 is the first clock signal. Details are not described one by one herein.

It should be noted that other circuit structures in this embodiment are the same as those in Embodiment 1. Details are not described one by one herein.

### Embodiment 3

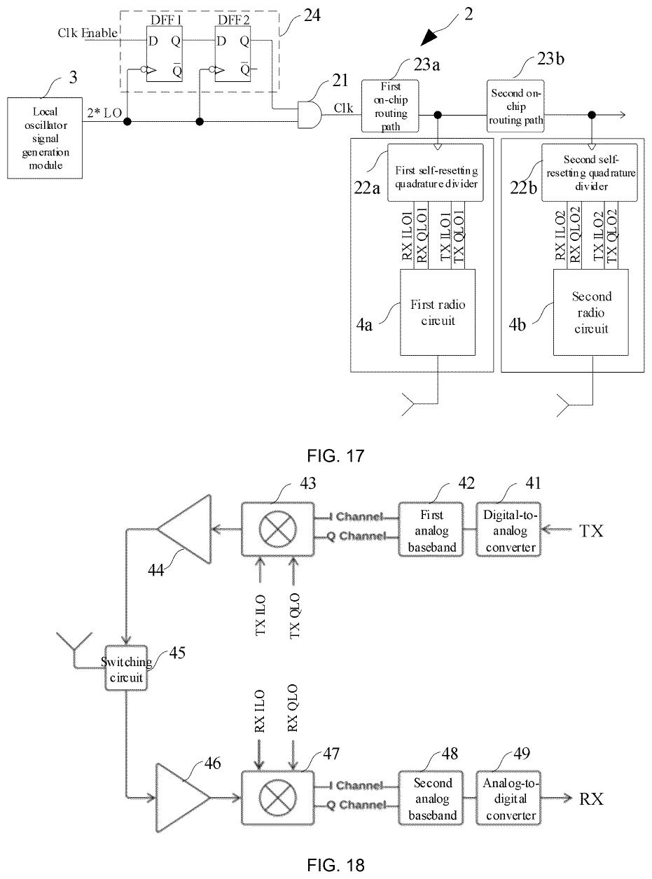

As shown in FIG. 17, this embodiment provides a multi-chain radio circuit system. The multi-chain radio circuit system includes:

A quadrature divider circuit 2, a local oscillator signal generation module 3, and k radio circuits.

As shown in FIG. 17, the local oscillator signal generation module 3 is configured to generate a clock signal 2*LO.

Specifically, the structure of the local oscillator signal generation module 3 is not limited. Any circuit structure that can generate the clock signal 2*LO is applicable to the present disclosure, which is not individually limited herein. For example, the local oscillator signal generation module 3 may be one or more of a signal synthesizer, a custom frequency source, or a direct digital synthesizer.

As shown in FIG. 17, the quadrature divider circuit 2 is connected to an output terminal of the local oscillator signal generation module 3 and generates an in-phase local oscillator signal and a quadrature local oscillator signal required for transmission and reception for each of the k radio circuits based on the clock signal.

Specifically, the quadrature divider circuit 2 may use the quadrature divider circuit in Embodiment 1 or Embodiment 2. Details of specific structures are not described one by one herein.

As shown in FIG. 17, each radio circuit receives the corresponding in-phase local oscillator signal and quadrature local oscillator signal, and is configured to implement transmission and reception of a radio signal.

Specifically, each of the radio circuits corresponds to one of the self-resetting quadrature dividers in the quadrature divider circuit 2. In this embodiment, two radio circuits are provided, which are respectively a first radio circuit 4a and a second radio circuit 4b. The first radio circuit 4a and the first self-resetting quadrature divider 22a form one complete link, and the second radio circuit 4b and the second self-resetting quadrature divider 22b form one complete link. That is, the first self-resetting quadrature divider 22a provides mutually quadrature signals to the first radio circuit 4a, and the second self-resetting quadrature divider 22b provides mutually quadrature signals to the second radio circuit 4b.

Specifically, as shown in FIG. 18, in this embodiment, each radio circuit includes a transmit path, a receive path, a switching circuit 45, and an antenna. The transmit path receives a first group of mutually quadrature local oscillator signals TX ILO and TX QLO, and performs up-conversion based on the first group of mutually quadrature local oscillator signals to obtain a to-be-transmitted radio frequency signal. As an example, the transmit path includes a digital-to-analog converter 41, a first analog baseband 42, an upconverter 43, and a power amplifier 44. The digital-to-analog converter 41 converts a to-be-transmitted signal TX into an analog signal. An output signal of the digital-to-analog converter 41 is passed through the first analog baseband 42, then fed into the upconverter 43, where it is mixed with the local oscillator signals TX ILO and TX QLO. The power amplifier 44 amplifies an output signal of the upconverter 43. The receive path receives a second group of mutually quadrature local oscillator signals, RX ILO and RX QLO, and performs down-conversion on the received radio frequency signal based on the second group of mutually quadrature local oscillator signals. As an example, the receive path includes a low noise amplifier 46, a downconverter 47, a second analog baseband 48, and an analog-to-digital converter 49. The low noise amplifier 46 amplifies the received radio frequency signal. The downconverter 47 mixes an output signal of the low noise amplifier 46 with the local oscillator signals RX ILO and RX QLO. The mixed signal is passed through the second analog baseband 48 and then fed into the analog-to-digital converter 49 to be converted into a digital signal RX. A first terminal of the switching circuit 45 is connected to the antenna, and a second terminal of the switching circuit 45 switches between the transmit path and the receive path, enabling the transmit path and the receive path to share the antenna.

It should be noted that the structure of the radio circuit and the quantity of required mutually quadrature local oscillator signals include, but are not limited to, the structure listed in this embodiment. Details are not described one by one herein.

### Embodiment 4

This embodiment provides a synchronization method for a quadrature divider circuit. In this embodiment, the synchronization method for the quadrature divider circuit is implemented based on the quadrature divider circuit in Embodiment 1. In practical use, any circuit that can implement this method is applicable. The synchronization method for the quadrature divider circuit includes:

S1). When a clock enable signal Clk Enable is valid, a clock signal 2*LO is enabled as a gated clock Clk, which is provided to k radio circuits. The self-resetting quadrature divider in each radio circuit generates an in-phase local oscillator signal and a quadrature local oscillator signal required for transmission and reception of the current radio circuit based on the gated clock Clk. The frequency of the clock signal 2*LO is twice that of the local oscillator signal, and k is a natural number greater than 1.

Specifically, as shown in FIG. 13, when the clock enable signal Clk Enable is valid, the clock signal 2*LO is routed to each radio circuit. The quadrature divider in each radio circuit generates an in-phase local oscillator signal and a quadrature local oscillator signal based on the clock signal 2*LO, enabling the corresponding radio circuit to complete the transmission or reception of radio signals.

S2). When the clock enable signal Clk Enable is invalid, the clock signal 2*LO is disabled, and the self-resetting quadrature divider in each of the radio circuits performs a self-reset. They will resume operation from a preset reset state once the clock signal 2*LO is re-enabled.

Specifically, as shown in FIG. 13, when the clock enable signal Clk Enable is invalid, the clock signal 2*LO is disabled, and the gated clock Clk is at a low level. The gated clock Clk is routed to each radio circuit, and the self-resetting quadrature divider in each radio circuit generates a reset signal rstb after a corresponding delay. When the reset signal rstb is valid, the quadrature divider in each radio circuit performs a self-reset. Each output signal of the self-resetting quadrature dividers is set to a desired state after the self-reset, as required.

Specifically, as shown in FIG. 13, when the clock enable signal Clk Enable is restored to valid, the clock signal 2*LO (re-enabled) is routed back to each radio circuit. The reset signal rstb becomes invalid in the first cycle after the clock signal 2*LO is restored. Each self-resetting quadrature divider resumes operation from the preset reset state, ensuring that there is no uncertainty in the output signal state of the quadrature divider.

It should be noted that the reset times of the self-resetting quadrature dividers do not necessarily occur at the same time. In this embodiment, they are assumed to occur at the same time for simplicity. Similarly, the times at which the self-resetting quadrature dividers are re-enabled do not necessarily occur at the same time. The key is to ensure that the output signal state of each self-resetting quadrature divider is determined when it is re-enabled, and this is not limited to this embodiment.

As another implementation of the present disclosure, the synchronization method for the quadrature divider circuit further includes a step of synchronizing the clock enable signal and a clock signal before the gated clock is generated. For specific principles, refer to Embodiment 1. Details are not described one by one herein.

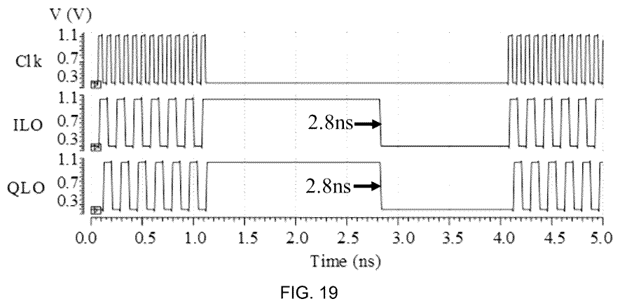

As shown in FIG. 19, the simulation diagram of the output signals of the self-resetting quadrature dividers of this method illustrates that the outputs ILO and QLO of the self-resetting quadrature dividers are simultaneously reset at 2.8 ns. Additionally, the reset states are identical, ensuring that when the clock restarts at 4.1 ns, the self-resetting quadrature dividers will be in a predictable phase state.

### Embodiment 5

This embodiment provides a synchronization method for a quadrature divider circuit. In this embodiment, the synchronization method for the quadrature divider circuit is implemented based on the quadrature divider circuit in Embodiment 2. The key difference from Embodiment 4 lies in that the clock signal is a differential signal. The clock enable signal is used to enable and disable a first clock signal, and a differential gated clock is generated based on the first clock signal and a second clock signal. Specifically, the first clock signal and the second clock signal are differential signals, and the frequencies of the first clock signal and the second clock signal are twice that of the local oscillator signal. Additionally, the detection of the gated clock is realized by performing an XOR operation on the first clock signal and the second clock signal. For specific principles, refer to Embodiment 2. Details are not described one by one herein.

In conclusion, the present disclosure provides a multi-chain radio circuit system, a quadrature divider circuit, and a synchronization method. The quadrature divider circuit includes: a logic unit and k self-resetting quadrature dividers, k is a natural number greater than 1. A first input terminal of the logic unit is connected to a clock enable signal, a second input terminal of the logic unit is connected to a clock signal, and a gated clock is output. When a clock enable signal is valid, a clock signal is enabled as a gated clock, and when the clock enable signal is invalid, the clock signal is disabled. The frequency of the clock signal is twice that of a local oscillator signal. Each self-resetting quadrature divider is connected to an output terminal of the logic unit. When the clock signal is disabled, self-resetting is performed, and when the clock signal is enabled, an in-phase local oscillator signal and a quadrature local oscillator signal required for transmission and reception of a corresponding radio circuit are generated. The multi-chain radio circuit system, the quadrature divider circuit, and the synchronization method of the present disclosure can synchronously modulate the clock enable signal and the clock signal, and detect the modulated signals. When it is detected that the clock signal is disabled, a self-reset signal of the frequency divider is generated. During radio wake-up, beam steering is always employed without sacrificing link throughput. Each radio circuit uses its own local oscillator signal, simplifying the wiring and reducing the generation of radiated spurious tones. Additionally, there is no need to use an explicit reset signal or to ensure that the reset signal satisfies potentially stringent timing constraints. Therefore, the present disclosure effectively overcomes the various shortcomings of the prior art and has significant industrial application value.

The above embodiments are merely illustrative of the principles and effects of the present disclosure, and are not intended to limit the present disclosure. Any person skilled in the art may modify or change the above embodiments without departing from the spirit and scope of the present disclosure. Therefore, all equivalent modifications or changes made by a person skilled in the art without departing from the spirit and technical concept disclosed by the present disclosure shall still fall within the claims of the present disclosure.

1. A quadrature divider circuit at least comprising:
a logic unit and k self-resetting quadrature dividers, wherein k is a natural number greater than 1;
wherein a first input terminal of the logic unit is connected to a clock enable signal, a second input terminal of the logic unit is connected to a clock signal, and a gated clock is output; wherein when the clock enable signal is valid, the clock signal is enabled as the gated clock, and when the clock enable signal is invalid, the clock signal is disabled, wherein a frequency of the clock signal is twice that of a local oscillator signal; and
wherein each of the self-resetting quadrature dividers is connected to an output terminal of the logic unit, wherein when the clock signal is disabled, self-resetting is performed, and when the clock signal is enabled, an in-phase local oscillator signal and a quadrature local oscillator signal required for transmission and reception of a corresponding radio circuit are generated.

2. The quadrature divider circuit according to claim 1, wherein each of the self-resetting quadrature dividers comprises a reset unit and a quadrature divider;
wherein the reset unit is connected to an output terminal of the logic unit, wherein when the gated clock is running, an invalid reset signal is generated, and when the gated clock is stopped for a preset time, a valid reset signal is generated; and
wherein an input terminal of the quadrature divider is connected to an output terminal of the logic unit, a reset terminal of the quadrature divider is connected to an output terminal of the reset unit, wherein when the reset signal is valid, the quadrature divider is reset, and when the reset signal is invalid, the quadrature divider generates the in-phase local oscillator signal and the quadrature local oscillator signal based on the gated clock.

3. The quadrature divider circuit according to claim 2, wherein the reset unit comprises a timer and a logic NOT gate;
wherein the timer is connected to an output terminal of the logic unit and is configured to measure duration for which the gated clock is stopped and generate a corresponding timing voltage; and
wherein the logic NOT gate is connected to an output terminal of the timer and generates a valid reset signal when the timing voltage reaches a preset value.

4. The quadrature divider circuit according to claim 3, wherein the timer comprises a current source, a pull-down transistor, and a capacitor,
wherein one terminal of the current source is connected to a supply voltage, and the other terminal of the current source is grounded through the pull-down transistor;
wherein a control terminal of the pull-down transistor is connected to an output terminal of the logic unit; and
wherein the capacitor is connected in parallel across two terminals of the pull-down transistor.

5. The quadrature divider circuit according to any one of claims 1 to 4, wherein the quadrature divider circuit further comprises an enable synchronization unit, and the enable synchronization unit comprises n-stage D flip-flops, wherein n is a natural number greater than or equal to 1;
when n is equal to 1, a data input of the D flip-flop is connected to the clock enable signal, a clock input of the D flip-flop is connected to the clock signal, and an output of the D flip-flop is connected to the first input terminal of the logic unit; and
when n is greater than or equal to 2, the D flip-flops are cascaded sequentially, a data input of the first-stage D flip-flop is connected to the clock enable signal, a data input of each subsequent-stage D flip-flop is connected to an output of the previous-stage D flip-flop in sequence, a clock input of each of the D flip-flops is connected to the clock signal, and an output of the last-stage D flip-flop is connected to the first input terminal of the logic unit.

6. A quadrature divider circuit at least comprising:
a logic unit and k self-resetting quadrature dividers, wherein k is a natural number greater than 1;
wherein a first input terminal of the logic unit is connected to a clock enable signal, and a second input terminal of the logic unit is connected to a first clock signal; wherein when the clock enable signal is valid, the first clock signal is enabled, and when the clock enable signal is invalid, the first clock signal is disabled; a differential gated clock is generated based on an output signal of the logic unit and a second clock signal, wherein the first clock signal and the second clock signal are differential signals, and frequencies of the first clock signal and the second clock signal are twice that of a local oscillator signal; and
wherein each of the self-resetting quadrature dividers receives the gated clock, wherein when the first clock signal is disabled, self-resetting is performed, and when the first clock signal is enabled, an in-phase local oscillator signal and a quadrature local oscillator signal required for transmission and reception of a corresponding radio circuit are generated.

7. The quadrature divider circuit according to claim 6, wherein each of the self-resetting quadrature dividers comprises a reset unit and a quadrature divider;
wherein the reset unit is connected to an output terminal of the logic unit, when the output signal of the logic unit is running, an invalid reset signal is generated, and when the output signal of the logic unit is stopped, a valid reset signal is generated; and
wherein an input terminal of the quadrature divider is connected to the gated clock, a reset terminal of the quadrature divider is connected to an output terminal of the reset unit, wherein when the reset signal is valid, the quadrature divider is reset, and when the reset signal is invalid, the quadrature divider generates the in-phase local oscillator signal and the quadrature local oscillator signal based on the gated clock.

8. The quadrature divider circuit according to claim 7, wherein the reset unit comprises an XOR gate; and input terminals of the XOR gate are respectively connected to an output terminal of the logic unit and the second clock signal, and an output terminal of the XOR gate is connected to the reset terminal of the quadrature divider.

9. The quadrature divider circuit according to any one of claims 6 to 8, wherein the quadrature divider circuit further comprises an enable synchronization unit, and the enable synchronization unit comprises n-stage D flip-flops, wherein n is a natural number greater than or equal to 1;
when n is equal to 1, a data input of the D flip-flop is connected to the clock enable signal, a clock input of the D flip-flop is connected to the first clock signal, and an output of the D flip-flop is connected to the first input terminal of the logic unit; and
when n is greater than or equal to 2, the D flip-flops are cascaded sequentially, a data input of the first-stage D flip-flop is connected to the clock enable signal, a data input of each subsequent-stage D flip-flop is connected to an output of the previous-stage D flip-flop in sequence, a clock input of each of the D flip-flops is connected to the first clock signal, and an output of the last-stage D flip-flop is connected to the first input terminal of the logic unit.

10. The quadrature divider circuit according to claim 1 or 2, wherein the gated clock is routed to each of the self-resetting quadrature dividers through an on-chip routing path.

11. A multi-chain radio circuit system, at least comprising:
a local oscillator signal generation module, k radio circuits, and the quadrature divider circuit according to any one of claims 1 to 10;
the local oscillator signal generation module is configured to generate a clock signal;
the quadrature divider circuit is connected to an output terminal of the local oscillator signal generation module, and generates an in-phase local oscillator signal and a quadrature local oscillator signal required for transmission and reception for each of the k radio circuits based on the clock signal; and
each of the radio circuits receives the corresponding in-phase local oscillator signal and quadrature local oscillator signal and is configured to implement transmission and reception of a radio signal.

12. The multi-chain radio circuit system according to claim 11, wherein each of the radio circuits comprises a transmit path, a receive path, a switching circuit, and an antenna;
the transmit path receives a first group of mutually quadrature local oscillator signals, and performs up-conversion based on the first group of mutually quadrature local oscillator signals to obtain a to-be-transmitted radio frequency signal;
the receive path receives a second group of mutually quadrature local oscillator signals, and performs down-conversion on the received radio frequency signal based on the second group of mutually quadrature local oscillator signals; and
a first terminal of the switching circuit is connected to the antenna, and a second terminal of the switching circuit switches between the transmit path and the receive path.

13. A synchronization method for a quadrature divider circuit at least comprising:
when a clock enable signal is valid, enabling a clock signal as a gated clock, wherein the gated clock is provided to k radio circuits, and a quadrature divider in each of the radio circuits generates an in-phase local oscillator signal and a quadrature local oscillator signal required for transmission and reception of the current radio circuit based on the gated clock, wherein a frequency of the clock signal is twice that of a local oscillator signal, and k is a natural number greater than 1; and
when the clock enable signal is invalid, disabling the clock signal, wherein the quadrature divider in each of the radio circuits performs a self-reset and resumes operation from a preset reset state after the clock signal is re-enabled.

14. A synchronization method for a quadrature divider circuit at least comprising:
when a clock enable signal is valid, enabling a first clock signal, generating a differential gated clock based on the first clock signal and a second clock signal, wherein the gated clock is provided to k radio circuits, and a quadrature divider in each of the radio circuits generates an in-phase local oscillator signal and a quadrature local oscillator signal required for transmission and reception of the current radio circuit based on the gated clock, wherein the first clock signal and the second clock signal are differential signals, frequencies of the first clock signal and the second clock signal are twice that of a local oscillator signal, and k is a natural number greater than 1; and
when the clock enable signal is invalid, disabling the first clock signal, wherein the quadrature divider in each of the radio circuits performs a self-reset and resumes operation from a preset reset state after the clock signal is re-enabled.

15. The synchronization method for the quadrature divider circuit according to claim 13 or 14, wherein the synchronization method for the quadrature divider circuit further comprises a step of synchronizing the clock enable signal and the clock signal before the gated clock is generated.
